(19) United States
(12) Patent Application Publication
(10) Pub. No.: US 2013/0299227 A1
(43) Pub. Date: Nov. 14, 2013

(54) NEW PRINTED CIRCUIT BOARD AND METHOD FOR MANUFACTURING SAME

(71) Applicants: Eun Yong Chung, Yongin-si (KR); Kyung Woon Cho, Yongin-si (KR); Tae Sik Eo, Seongnam-si (KR); Woo Hyun Noh, Suwon-si (KR)

(72) Inventors: Eun Yong Chung, Yongin-si (KR); Kyung Woon Cho, Yongin-si (KR); Tae Sik Eo, Seongnam-si (KR); Woo Hyun Noh, Suwon-si (KR)

(73) Assignee: DOOSAN CORPORATION, Seoul (KR)

(21) Appl. No.: 13/883,424

(22) PCT Filed: Nov. 4, 2011
(86) PCT No.: PCT/KR11/08369

§ 371 Date: Jul. 24, 2013

(30) Foreign Application Priority Data
Nov. 5, 2010 (KR) 10-2010-0110024

(51) Int. Cl. H05K 1/11; H05K 3/10

(52) U.S. Cl. CPC H05K 1/115; H05K 3/10
USPC 174/266; 174/250; 29/846; 29/852

(57) ABSTRACT

The present invention relates to a laminated body for forming a printed circuit board comprising: a separation member in which first conductive layers and second conductive layers separable from each other are sequentially provided on each of upper and lower surfaces of a separating-insulation member; a laminating-insulation member sequentially laminated on each of the upper and lower surfaces of the separation member; and a conductive layer sequentially laminated on each of upper and lower surfaces of the insulation member, a printed circuit board comprising the laminated body, and a method of manufacturing the same. The present invention provides the new multi-layer printed circuit board to which various designs, such as a double-sided structure or an unbalanced structure, are applicable while overcoming an application limitation of a single-sided printed circuit board structure in the related art, thereby improving productivity and economic feasibility.

### TECHNICAL FIELD

The present invention relates to a new printed circuit board capable of obtaining productivity and economic feasibility while exhibiting a high degree of design freedom of the printed circuit board, such as a double-sided structure, a multi-layer structure, or an unbalanced structure, and a method of manufacturing the same.

### BACKGROUND ART

A printed circuit board (PCB) is a component configured so that various elements are mounted or elements are electrically connectable by integrating wires. According to the development of technology, printed circuit boards having various forms and functions have been manufactured.

A method of manufacturing a single-sided printed circuit board in the related art uses a separation member. For example, referring to FIG. 1, a separation member 110 is disposed between two insulation members 111 and 112 and then conductive layers 113 and 114 are formed on exterior surfaces of the insulation members 111 and 112, respectively, and a circuit pattern is formed on the formed conductive layers 113 and 114 and then the insulation members 111 and 112 are separated based on the separation member 110.

The aforementioned manufacturing method has a problem in that the method is limited to a method of manufacturing a printed circuit board having a single-sided structure in which an electronic device is mounted in the insulation member, and is connected to a connection terminal by a wire passing through a through-hole provided at the insulation member. Further, there is a high possibility of generating wrinkles on a surface of the separation member according to resin contents of the insulation member, and further, it is difficult to control a warpage characteristic even through resin contents are adjusted or another method is used.

Accordingly, the development of a printed circuit board having a new structure, by which various designs, such as a double-sided structure, a multi-layer structure, and an unbalanced structure, are applicable and productivity and economic feasibility are obtained, has been urgently demanded.

### DISCLOSURE

### Technical Problem

Accordingly, an object of the present invention is to provide a printed circuit board having a new structure, by which various designs, such as a multi-layer structure, a double-sided structure, and an unbalanced structure, are applicable and simplicity and economic feasibility of a manufacturing process are promoted, and a method of manufacturing the same.

Other technical objects to be achieved in the present invention are not limited to the aforementioned technical objects, and other not-mentioned technical objects will be obviously understood by those skilled in the art from the description below.

### Technical Solution

In order to resolve the technical problem, a printed circuit board having a new structure of the present invention may be manufactured by (a) a step of preparing a separation member in which first conductive layers and second conductive layers separable from each other are sequentially provided on each of upper and lower surfaces of a separating-insulation member; (b) a step of sequentially laminating first insulation members and pattern forming-first conductive layers on each of upper and lower surfaces of the separation member; (c) a step of forming first conductive circuit patterns on one region of the laminated first conductive layers; (d) a step of sequentially laminating and compressing second insulation members and pattern forming-second conductive layers on each of the formed first conductive circuit patterns; (e) a step of forming a laminated body in which the conductive circuit pattern is laminated by n layers or more by repeating steps (c) and (d) (here, n is a natural number between 1 and 10); and (f) a step of separating each of the laminated bodies to which the second conductive layers are attached by detaching the separating-insulation member and the first conductive layers from the separation member.

The second conductive layers of the separation member may be attached to the laminated body to form wiring, and the first conductive layers are separated from the second conductive layers.

The pattern forming-conductive layers positioned on uppermost/lowermost surfaces of the laminated body formed in step (e), respectively, may have a mono-layer structure or a multi-layer structure having two or more layers.

In this case, when the pattern forming-conductive layers having the multi-layer structure are the second conductive layers and the first conductive layers, which are separable from each other, the process may proceed to step (f).

The structures of the laminated bodies separated from an upper portion and a lower portion of the separation member based on the separation member in step (f) may be the same as each other.

The method may further comprise a step of forming one or more through-holes vertically passing through the separated respective laminated bodies.

Further, the method may further include a step of plating second conductive layers provided on each of upper and lower surfaces of the separated respective laminated bodies and forming a circuit pattern.

The present invention provides a printed circuit board manufactured by the aforementioned manufacturing method.

The printed circuit board comprises: an insulation substrate part; an upper conductive circuit pattern part which is formed on an upper surface of the insulation substrate part, and in which one or more unit layers comprising a predetermined conductive circuit pattern are laminated; a lower conductive circuit pattern part which is formed on a lower surface of the insulation substrate part, and in which one or more unit layers comprising a predetermined conductive circuit pattern are laminated; and one or more through-holes provided so as to entirely pass through the insulation substrate part, the upper conductive circuit pattern part, and the lower conductive circuit pattern part, and configured to electrically connect the insulation substrate part, the upper conductive circuit pattern part, and the lower conductive circuit pattern part, in which the upper conductive circuit pattern part and the lower conductive circuit pattern part may have an unbalanced structure in a vertical direction based on the insulation substrate part.

Here, the upper conductive circuit pattern part and the lower conductive circuit pattern part may independently have a mono-layer structure or a multi-layer structure having two or more layers.

Further, the conductive circuit patterns included in the respective unit layers may have an unbalanced structure in view of a thickness, a shape, or a structure, or in view of all of the thickness, the shape, and the structure.

In this case, the insulation substrate part and the insulation layer included in each unit layer may independently have a different configuration in view of contents of a constituent resin, a material of a constituent resin, a coefficient of thermal expansion of the insulation layer, or a thickness of the insulation layer, or all of them.

In the meantime, the present invention provides a laminated body for forming a printed circuit board as an intermediate body for manufacturing a printed circuit board having a new structure, the laminated body including: a separation member in which first conductive layers and second conductive layers separable from each other are sequentially provided on each of upper and lower surfaces of a separating-insulation member; a laminating-insulation member sequentially laminated on each of the upper and lower surfaces of the separation member; and a conductive layer sequentially laminated on each of upper and lower surfaces of the insulation member.

In this case, an adhesive layer is included on an interface of the first conductive layer and the second conductive layer, and the first conductive layer and the second conductive layer may be separated from each other when force equal to or larger than 0.02 kgf/cm is applied.

### Advantageous Effects

The novel method of manufacturing the printed circuit board according to the present invention may be applicable to a printed circuit board structure having a double-sided structure, an unbalanced structure, and a multi-layer structure, in addition to a single-sided printed circuit board, which allows a high degree of design freedom of a printed circuit board.

Further, since the separation member is used, it is possible to simultaneously manufacture a plurality of printed circuit boards, thereby improving productivity of a manufacturing process.

Furthermore, it is possible to apply a coreless structure to which copper clad laminates (CCL) are not applied, thereby considerably decreasing a thickness of a printed circuit board.

Moreover, it is possible to simplify manufacturing by minimizing warpage during a manufacturing process caused by an unbalanced structure of the printed circuit board and a structural warpage characteristic of a final product.

### DESCRIPTION OF DRAWINGS

FIG. 1 is a cross-sectional view illustrating a configuration of a single-sided printed circuit board according to the related art.

FIG. 2 is a cross-sectional view illustrating a configuration of a printed circuit board according to an exemplary embodiment of the present invention.

FIGS. 3 to 10 are cross-sectional views illustrating a process of manufacturing the printed circuit board according to the exemplary embodiment of the present invention.

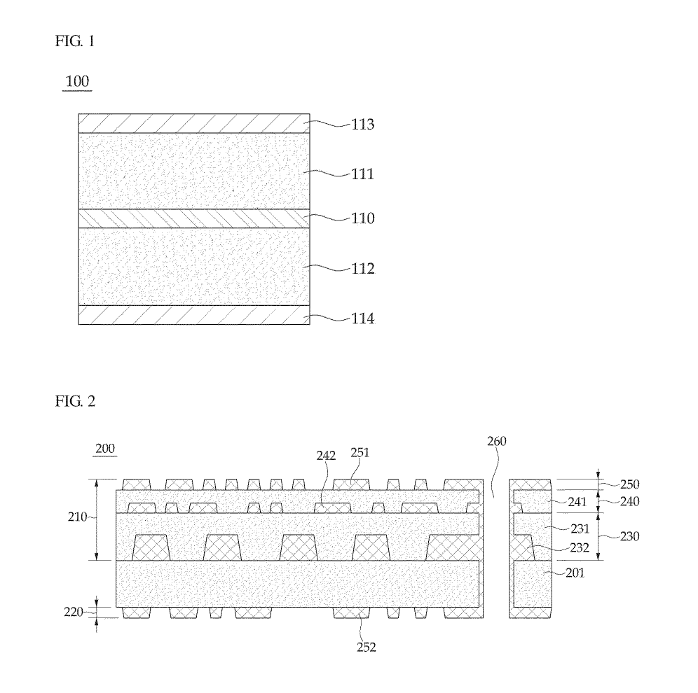

### BEST MODE

Hereinafter, a printed circuit board according to an exemplary embodiment of the present invention will be described in detail with reference to the accompanied drawings.

FIG. 2 is a cross-sectional view illustrating a configuration of a printed circuit board according to an exemplary embodiment of the present invention.

A printed circuit board 200 according to the present invention comprises: an insulation substrate part 201; an upper conductive circuit pattern part 210 positioned on an upper surface of the insulation substrate part; a lower conductive circuit pattern part 220 positioned on a lower surface of the insulation substrate part; and one or more through-holes 260 provided so as to entirely pass through the insulation substrate part 201, the upper conductive circuit pattern part 210, and the lower conductive circuit pattern part 220, and configured to electrically connect the upper conductive circuit pattern part 210 and the lower conductive circuit pattern part 220.

Here, the upper conductive circuit pattern part 210 may have a form in which one or more unit layers 230, 240, and 250 formed on the upper surface of the insulation substrate part 201 and having conductive circuit patterns 232, 242, and 251 having a predetermined shape are laminated. Similarly, the lower conductive circuit pattern part 220 may have a form in which one or more unit layer 220 formed on the lower surface of the insulation substrate part 201 and having a conductive circuit pattern 252 having a predetermined shape are laminated.

In this case, the upper conductive circuit pattern part 210 and the lower conductive circuit pattern part 210 may have an unbalanced structure in a vertical direction based on the insulation substrate part 201. For example, the upper conductive circuit pattern part 210 and the lower conductive circuit pattern part 210 may have the unbalanced structure because thicknesses or the number of layers of the respective unit layers 220, 230, 240, and 250 are different from each other, or because shapes, thicknesses, or structures of the conductive circuit patterns 232, 242, and 252 are different from each other.

The insulation substrate part 201 serves to form an appearance of the printed circuit board and provide durability while electrically insulating the respective connected layers from each other.

A thermosetting resin having an adhesive characteristic may be used for the insulation substrate part 201 without limitation, and the insulation substrate part 201 may be formed of a soft material, such as polyimide (PI); and a hard material using a mixed material, such as glass fabric, BT, epoxy, and a phenol resin. Non-limited examples of the usable insulation member include an epoxy resin including glass fabric, a phenol resin, a prepreg formed by laminating epoxy on carbon, or a mixed form thereof.

The upper conductive circuit pattern part 210 and the lower conductive circuit pattern part 220 are formed on the upper and lower surfaces of the insulation substrate part 210, respectively, and in this case, each of the upper and lower conductive circuit pattern parts 210 and 220 may be independently a mono-layer, or a multi-layer structure in which the two or more unit layers are laminated.

In the present invention, the unit layers 220, 230, 240, and 250 refer to a monolayer in which conductive circuit patterns having a predetermined shape are laminated. In this case, each unit layer may be a form 230 or 240 including an insulation layer or a form 220 or 250 including no insulation layer. Further, thicknesses of the respective unit layers 220, 230, 240, and 250 may be independently different from or the same as each other, and thicknesses of the conductive circuit patterns 232, 242, 251, and 252 contained in the respective unit layers 220, 230, 240, and 250 may also be different from or the same as each other. For example, a thickness of the conductive circuit pattern included in each unit layer may be a range from 8 μm to 70 μm, and a thickness of the insulation layer included in each unit layer may be a range from 15 μm to 150 μm. The whole thickness of the upper and lower unit layers may be appropriately adjusted as necessary.

In a case where the upper conductive circuit pattern part 210 has the multi-layer structure, the parts 230 and 240 of the unit layers includes insulation layers 231 and 241 having the conductive circuit patterns 232 and 242 on one surface, and the uppermost unit layer 250 may have a form in which the conductive circuit pattern 251 is exposed to the upper surface of the insulation substrate part.

In this case, if the insulation layers 231 and 241 included in the conductive circuit pattern parts are made of a polymer material capable of electrically insulating the respective layers which are connected with each other, the insulation layers 231 and 241 are not particularly limited. For example, the insulation layers 231 and 241 may be formed of a material, such as an epoxy resin and a phenol resin, and may be the same as an ingredient of the insulation substrate part 201. A coefficient of thermal expansion may be adjusted by generally and uniformly distributing an inorganic filler, glass fabric, or the like on the insulation layer, and a coefficient of thermal expansion of each of the polymer material and the glass fabric may be adjusted for use.

Further, the conductive circuit patterns 232, 242, 251, and 252 may have a metal thin film form made of a conductive material, and may be made of copper. The lower conductive circuit pattern part 220 may also have the same structure and/or configuration as that of the aforementioned upper conductive circuit pattern part.

In the present invention, a sum of the respective unit layers 220, 230, 240, and 250 constituting the upper conductive circuit pattern part 210 and the lower conductive circuit pattern part 220 may be an even number or an odd number. Especially, in the related art, only a printed circuit board having a balanced structure by applying copper clad laminates (CCL) is avoidably and limitedly manufactured in the related art in order to minimize a warpage problem. Contrary to this, the present invention has advantages in that the copper foil and the insulation layers are formed to have different thicknesses or the printed circuit board having the multi-layer structure having no limitation in the number of layers may be freely designed, and the printed circuit board may be manufactured without a warpage problem.

In the meantime, FIG. 2 simply exemplifies the upper conductive circuit pattern part 210 having the multi-layer structure comprising the plurality of unit layers 230, 240, and 250, but the present invention is not limited thereto. In addition, the configuration that the lower conductive circuit pattern part 220 has a multi-layer structure, or the configuration that both the upper conductive circuit pattern part 210 and the lower conductive circuit pattern part 220 have a multi-layer structure also belongs to the scope of the present invention.

A method of manufacturing the printed circuit board according to the present invention may include steps below.

According to an exemplary embodiment of the method of manufacturing the printed circuit board may comprise: (a) a step of preparing a separation member in which first conductive layers and second conductive layers separable from each other are sequentially provided on each of the upper and lower surfaces of a separating-insulation member; (b) a step of sequentially laminating first insulation members and pattern forming-first conductive layers on each of upper and lower surfaces of the separation member; (c) a step of forming first conductive circuit patterns on one region of the laminated first conductive layers; (d) a step of sequentially laminating and compressing second insulation members and pattern forming-second conductive layers on each of the formed first conductive circuit patterns; (e) a step of forming a laminated body in which the conductive circuit pattern is laminated by n layers or more by repeating steps (c) and (d) (here, n is a natural number between 1 and 10); and (f) a step of separating each of the laminated bodies to which the second conductive layers are attached by detaching the separating-insulation member and the first conductive layers from the separation member.

In this case, in the method of manufacturing the printed circuit board, steps (b) to (e) may be equally performed on both the upper and lower portions of the separation member based on the separation member.

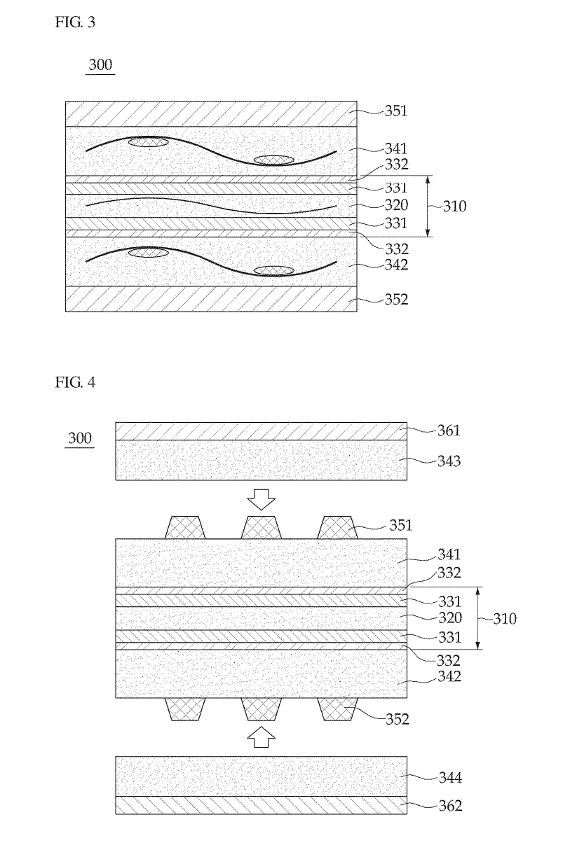

Hereinafter, a process of manufacturing the printed circuit board according to the exemplary embodiment of the present invention will be described in detail with reference to accompanying FIGS. 3 to 10.

1) A separation member 310 is prepared.

Referring to FIG. 3, the separation member 310 has a form in which first conductive layers 331 and second conductive layers 332 which are separable from each other are sequentially provided on each of upper and lower surfaces of a separating-insulation member 320. In this case, the first conductive layer 331 for the separation member serves to protect the second conductive layer, and be separated from the second conductive layer in a separation step. The second conductive layers 332 are attached to an upper insulation member 341 and a lower insulation member 342 forming a laminated body, respectively, to serve as seed layers to form wiring.

The first conductive layer 331 and the second conductive layer 332 for the separation member have a form of a metal thin film made of a conductive material, and may be made of copper.

In this case, the first conductive layer 331 and the second conductive layer 332 include an adhesive layer interposed therebetween, thereby having a heat-resistant property and an anti-corrosion property. Further, the first conductive layer 331 and the second conductive layer 332 may be stably attached to another base in a general state due to an adhesive ingredient contained in the adhesive layer, but in a case where force equal to or larger than 0.02 kgf/cm, preferably, force ranging from 0.02 to 0.045 kgf/cm, is applied, the first conductive layer 332 and the second conductive layer are separable from each other without physical damage.

A thickness of each of the first conductive layer 331 and the second conductive layer 332 for the separation member may be range from 8 μm to 70 μm, and it is preferable that the thickness of the first conductive layer 331 is larger than that of the second conductive layer 332 in order to protect the second conductive layer.

The separating-insulation member 320 serves as a supporting body of the first conductive layer 331 and the second conductive layer 332. Further, the separating-insulation member 320 is removed together with the first conductive layers in the separation step.

2) A first laminated body is formed by sequentially laminating a first insulation member and a pattern forming-first conductive layer on each of upper and lower surfaces of the separation member (see FIG. 3).

The first laminated body 300 comprises laminating-first insulation members 341 and 342 sequentially laminated on the upper and lower surfaces of the aforementioned separation member, respectively, and first conductive layers 351 and 352 sequentially laminated on upper and lower surfaces of the laminating-first insulation member, respectively.

In this case, the first insulation members and the pattern forming-first conductive layers are independently disposed above and under the separation member based on the separation member, respectively, so that the first insulation members may be divided into the first upper insulation member 341 and the first lower insulation member 342. Further, the pattern forming-first conductive layers may also be divided into the pattern forming-first upper conductive layer 351 and the pattern forming-first lower conductive layer 352. Hereinafter, another configuration of the present invention used above and under the separation member based on the separation member may also be equally divided.

To describe in more detail with reference to FIG. 3, the pattern forming-first upper conductive layer 351, the first upper insulation member 341, the separation member 310, the first lower insulation member 342, and the pattern forming-first lower conductive layer 352 are sequentially laminated.

The first upper insulation member 341 and the first lower insulation member 342 serve to insulate the respective layers from each other, and may have the same configuration as that of the aforementioned separating-insulation member 320. All of the separating-insulation member 320, the first upper insulation member 341, and the first lower insulation member 342 may be formed of prepreg in a semi-hardening state (B-stage).

The pattern forming-first upper conductive layer 351 and first lower conductive layer 352 additionally serve to establish an electrical connection and also serve as a heat path in an internal layer. A range of a thickness of the conductive layer may be 8 μm to 36 μm, and may also be formed by 1 Oz or more.

The present invention has been described based on the example in which the pattern forming-first upper conductive layer 351, the first upper insulation member 341, the separation member 310, the first lower insulation member 342, and the pattern forming-first lower conductive layer 352 are sequentially laminated, but a partial modification of an order of the laminating thereof or the selective mixing of the constitution of the laminating belongs to the scope of the present invention as necessary.

3) First conductive circuit patterns having a predetermined shape are formed on one region of the laminated first conductive layers (see FIG. 4).

The first conductive circuit patterns symmetrically formed above and under the separation member, respectively, based on the separation member may be divided into a first upper conductive circuit pattern 351 and a first lower conductive circuit pattern 352.

In this case, a method of forming the circuit pattern is not particularly limited, and may employ a conventional method known to one skilled in the art.

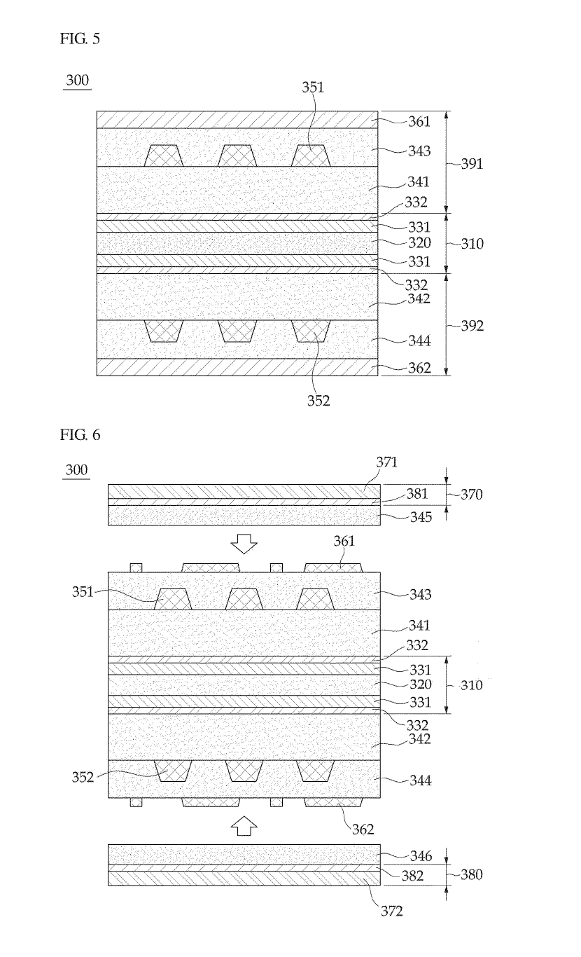

4) A second laminated body is formed by sequentially laminating and compressing second insulation members and pattern forming-second conductive layers on the first conductive circuit patterns positioned at an uppermost portion and a lowermost portion of the first laminated body (see FIGS. 4 and 5).

A more particular example of the manufacturing step will be described with reference to FIGS. 4 and 5. A second upper insulation member 343 and a pattern forming-second upper conductive layer 361 are sequentially laminated on the first upper conductive circuit pattern 351 formed on an upper surface of the first upper insulation member 341. Similarly, a second lower insulation member 344 and a pattern forming-second lower conductive layer 362 are sequentially laminated on the first lower conductive circuit pattern 352. Then, a second upper laminated body 391 and a second lower laminated body 392 are formed by compressing the first lower conductive circuit pattern 352, the second lower insulation member 344, and the pattern forming-second lower conductive layer 362.

In this case, the pattern forming-second upper conductive layer 361 and second lower conductive layer 362 may have a mono-layer structure or a multi-layer structure having two or more layers.

The formed second upper laminated body 391 may have a form in which the first upper conductive circuit pattern 351, the second upper insulation member 343, and the pattern forming-second upper conductive layer 361 are sequentially laminated on the first upper insulation member 341, and the second lower laminated body 392 may have a form in which the first lower conductive circuit pattern 352, the second lower insulation member 344, and the pattern forming-second lower conductive layer 362 are sequentially laminated on the first lower insulation member 342.

5) When the second upper conductive layer 361 and the second lower conductive layer 362 laminated on surfaces of the uppermost and lowermost portions of the second laminated body are the single conductive layer, an n^{th} laminated body in which the conductive circuit pattern is laminated by n layers or more is formed by sequentially repeating steps 3) and 4) n times. In this case, n is a natural number between 1 and 10.

For example, in a case where the steps 3) and 4) are repeatedly performed once from the first laminated body, each of the second upper laminated body 391 and the second lower laminated body 392 may include at least one layer, preferably, the two upper conductive circuit patterns and two lower conductive circuit patterns 351, 352, 361, and 362, and the two upper insulation layers and two lower insulation layers 343, 344, 341, and 342.

Even though multi-layer conductive layers which are not separated from each other based on the separation member 310 are applied as the pattern forming-second conductive layers 361 and 362, steps 3) and 4) may be repeatedly performed. In this case, the number of times of laminating of the conductive circuit pattern and the insulation member formed on the second laminated body 391 or 392 is not particularly limited, and may be appropriately adjusted as necessary.

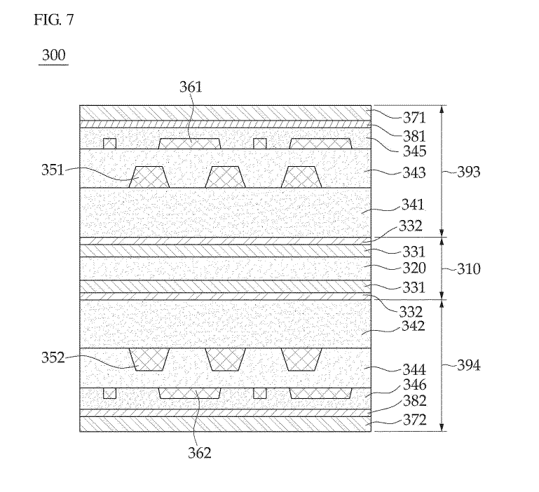

In the meantime, FIGS. 6 and 7 illustrate that the pattern forming-conductive layers having the multi-layer structure are introduced as the conductive layers laminated on the second laminated body and steps 3) and 4) are repeatedly performed once.

For example, in the manufacturing step, a third upper laminated body 393 and a third lower laminated body 394 are formed by laminating and then compressing a third upper insulation member 345 and a pattern forming-third upper conductive layer 370 on the second upper conductive circuit pattern 361, and a third lower insulation member 346 and a pattern forming-third lower conductive layer 380 on the second lower conductive circuit pattern 362, respectively.

Here, in a case where the pattern forming-third upper conductive layer 370 and third lower conductive layer 380 have a multi-layer structure having two or more layers, and include second conductive layers 381 and 382 and first conductive layers 371 and 372 which are separable from each other identically to the separation member 310, a separation step, which is a next process, may continue. In this case, even though a thin film-type single conductive layer is laminated as the third conductive layer 370 or 380, the separation step may continue as necessary.

The first conductive layers 371 and 372 serving the similar function to that of the first conductive layer of the separation member 310 are disposed on an upper surface of the third upper laminated body 393 and a lower surface of the third lower laminated body 394, which are formed as described above, respectively.

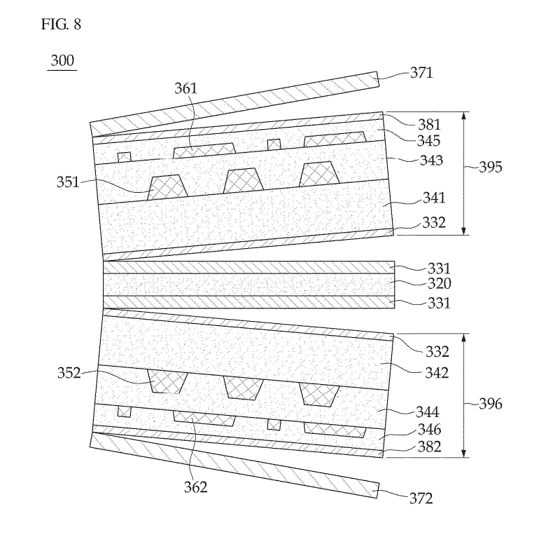

6) Each of the laminated bodies to which the second conductive layers are attached is separated by detaching the separation-insulation member and the first conductive layers from the separation member (see FIG. 8).

All of the third upper laminated body 393, the third lower laminated body 394, and the separation member 310 of the present invention comprise the first conductive layers 331, 371, and 372, and the second conductive layers 332, 381, and 382, which are separable from each other, respectively.

For example, referring to FIG. 8, it is possible to separate a fourth upper laminated body 395 and a fourth lower laminated body 396 of which upper and lower surfaces the second conductive layers 381, 382, and 332 are attached on by detaching the first conductive layer 331 and the separating-insulation member 320 from the separation member 310, and simultaneously, selectively detaching only the first conductive layers 371 and 372 positioned on the upper surface of the third upper laminated body 393 and the lower surface of the third lower laminated body 394, respectively.

The same manufacturing step is performed on each of the upper portion and the lower portion of the separation member 310 based on the separation member in the present invention, so that the structures of the laminated bodies 395 and 396 separated based on the separation member are the same as each other. For example, the laminated bodies 395 and 396 may have a structure in which the thin film-type second conductive layers 332, 381, and 382 are attached on the upper and lower surfaces of the separated fourth upper laminated body 395 and fourth lower laminated body 396, respectively, and the conductive circuit patterns 351, 352, 361, and 362 having the predetermined shape and the insulation layers 343, 344, 345, and 346 are alternately laminated inside the fourth laminated body by at least n layers or more.

In this case, even though the conductive circuit patterns 332, 351, 352, 361, 362, 381, and 382 included in the separated fourth upper laminated body 395 and fourth lower laminated body 396 have the unbalanced structure in a vertical direction, the vertically balanced structure between the upper laminated body and the lower laminated body is maintained during the aforementioned manufacturing process, so that a warpage characteristic generated during the manufacturing process may be minimized. Further, the printed circuit board having various structures may be simultaneously manufactured.

7) Then, one or more through-holes vertically passing through each separated laminated body are formed (see FIG. 9).

The through-hole 390 is formed for interlayer electrical connection through a plating process later. In this case, a position or a shape of the through-hole, and the number of through-holes are not particularly limited, and may be freely adjusted as necessary.

In order to form the through-hole 390, a conventional method known to one skilled in the art may be used, and for example, a mechanical drill, laser, and the like may be used. Although not illustrated in the drawing, in a case where laser is used, a method of forming a via-hole by irradiating laser to a portion in which the via-hole is to be formed may also be used. After the through-hole or the via-hole is formed as described above, a post treatment process of removing impurities formed on an inner wall during a process of processing the hole may be additionally included. Through this, it is possible to improve efficiency of the plating process to be performed later, and as a result, it is possible to improve reliability of a product.

8) A circuit pattern is formed after plating the second conductive layers provided on the upper and lower surfaces of the laminated body in which the through-hole is formed (see FIG. 9).

Referring to FIG. 9, since the second conductive layers 332 and 381 positioned on the upper and lower surfaces of the fourth upper laminated body 395, respectively, are formed in a thin film, plating layers 383 and 384 having a desired thickness may be further formed by using seeds 332 and 381. For example, a fine circuit wiring (50 pitches) may be formed on the second conductive layer. In this case, since the through-hole 390 is also plated, the printed circuit board is electrically connected.

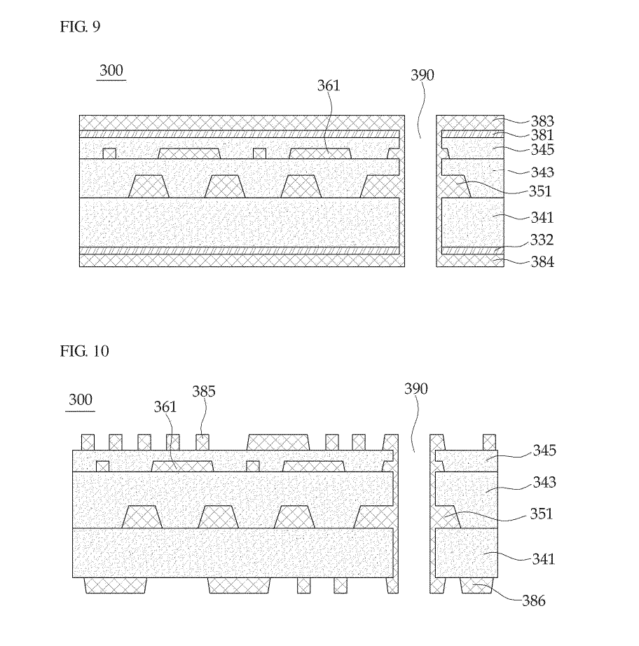

Then, as illustrated in FIG. 10, the printed circuit board is completely manufactured by forming circuit patterns 385 and 386 having a predetermined shape, and further performing a typical process of manufacturing the printed circuit board known to one skilled in the art, for example, a solder resist forming process, an etching and wiring process, and an electronic device mounting process, on each of the separated laminated bodies.

In the aforementioned method of manufacturing the printed circuit board, it is not necessary to sequentially perform the aforementioned respective steps in order to manufacture the printed circuit board, but the steps of the respective processes may be modified or selectively mixed for performance according to a design specification.

In the meantime, a warpage phenomenon of the printed circuit board is a very significant factor exerting a large influence on a process rate and productivity during the mounting of the printed circuit board, and further causing even an erroneous transference during a package assembling process or a failure of the electrical connection of the printed circuit board. The printed circuit board is a structure formed by laminating several materials, and a primary cause of the warpage phenomenon is a difference of a coefficient of thermal expansion (CTE) of each laminated material, and other known causes influencing the warpage phenomenon include Young's modulus of each material, a temperature change during the process, moisture absorption, and a mechanical load.

Since the warpage characteristic of the printed circuit board is mainly generated by a difference of thermal expansion and contraction between laminated materials and a load, a minimization of the warpage characteristic by changing a physical property, such as a composition, a thickness (dielectric thickness control), and a CTE of a laminated material laminated in multi-layers in order to decrease the difference is another characteristic of the present invention.

To this end, in the present invention, materials have different configurations in view of resin contents of the insulation member, a material or composition of a constituent resin, a coefficient of thermal expansion of a constituent ingredient of the insulation member, or a thickness of the insulation member, or all of them may be used as two or more insulation members used in laminating processes 2) to 5) of the aforementioned manufacturing step.

An exemplary embodiment of the present invention for controlling a warpage degree of the printed circuit board will be described below.

First, a warpage degree of the laminated body for forming the printed circuit board obtained for each manufacturing step or the finally manufactured printed circuit board is previously predicted or actually measured.

Then, when a value of predicted or actually measured warpage is a positive (+) value, the insulation member having a constitution capable of correcting the positive (+) value is used as the insulation member used in the laminating process later. For example, the insulation member and the like adjusted so as to have i) additional lower resin contents, ii) an additional smaller thickness, or iii) an additional lower coefficient of thermal expansion (CTE) may be used.

Contrary to this, when the value of the predicted or actually measured warpage value is a negative (−) value, the warpage degree may be corrected by adjusting the insulation member so as to have i) additional higher resin contents, ii) a higher coefficient of thermal expansion, and/or ii) an additional thicker thickness in the laminating process later.

In the present invention, it has been described as an example that the warpage is controlled by the control of the warpage by CTE matching or controlling resin contents and a dielectric thickness, such as a resin thickness, of the two or more insulation members laminated in the multi-layers, but the improvement of the warpage characteristic by forming the conductive layers and/or the conductive circuit patterns laminated in the multi-layers in the printed circuit board having a coreless form which does not use a copper clad laminate (CCL) core to have different thicknesses also belongs to the scope of the present invention.

As a result, the present invention may minimize the warpage phenomenon caused during the aforementioned manufacturing process, and may innovatively improve the warpage characteristic of an intermediate body for forming the printed circuit board obtained during the separation process or the finally manufactured printed circuit board.

In the above description, the present invention has been described based on the exemplary embodiments, but the exemplary embodiments are for illustration, and do not limit the present invention, and those skilled in the art will appreciate that various modifications and applications, which are not exemplified in the above description, may be made without departing from the scope of the essential characteristic of the present exemplary embodiments. For example, each constituent element specifically present in the exemplary embodiment may be modified and carried out. Further, the differences related to the modification and the application should be construed as being included in the scope of the present invention defined in the accompanying claims.

1-13. (canceled)

14. A method of manufacturing a printed circuit board, comprising:
(a) a step of preparing a separation member in which first conductive layers and second conductive layers separable from each other are sequentially provided on each of upper and lower surfaces of a separating-insulation member;
(b) a step of sequentially laminating first insulation members and pattern forming-first conductive layers on each of upper and lower surfaces of the separation member;
(c) a step of forming first conductive circuit patterns on one region of the laminated first conductive layers;
(d) a step of sequentially laminating and compressing second insulation members and pattern forming-second conductive layers on each of the formed first conductive circuit patterns;
(e) a step of forming a laminated body in which the conductive circuit pattern is formed by n layers or more by repeating steps (c) and (d) (here, n is a natural number between 1 and 10); and
(f) a step of separating each of the laminated bodies to which the second conductive layers are attached by detaching the separating-insulation member and the first conductive layers from the separation member.

15. The method of claim 14, wherein the second conductive layers of the separation member are attached to the laminated body to form wiring, and the first conductive layers are separated from the second conductive layers.

16. The method of claim 14, wherein a thickness of each of the first conductive layer and the second conductive layer ranges from 8 μm to 70 μm, and the thickness of the first conductive layer is larger than that of the second conductive layer.

17. The method of claim 14, wherein the pattern forming-conductive layers positioned on uppermost/lowermost surfaces of the laminated body formed in step (e), respectively, have a mono-layer structure or a multi-layer structure having two or more layers.

18. The method of claim 17, wherein when the pattern forming-conductive layers having the multi-layer structure are the second conductive layers and the first conductive layers, which are separable from each other, the process proceeds to step (f).

19. The method of claim 14, wherein structures of the laminated bodies separated from an upper portion and a lower portion of the separation member based on the separation member in step (f) are the same as each other.

20. The method of claim 19, wherein second conductive layers are positioned on upper and lower surfaces of the respective laminated bodies separated in step (f), and a conductive circuit pattern having a predetermined shape and an insulation layer are alternately laminated by n layers or more inside the laminated body.

21. The method of claim 20, further comprising:
a step of forming one or more through-holes vertically passing through the separated respective laminated bodies.

22. The method of claim 21, further comprising:
a step of plating second conductive layers provided on upper and lower surfaces of each of the separated laminated bodies and forming the circuit pattern.

23. A printed circuit board manufactured by the method claimed in claim 14.

24. The printed circuit board of claim 23, which comprises
an insulation substrate part;
an upper conductive circuit pattern part which is formed on an upper surface of the insulation substrate part, and in which one or more unit layers comprising a predetermined conductive circuit pattern are laminated;
a lower conductive circuit pattern part which is formed on a lower surface of the insulation substrate part, and in which one or more unit layers comprising a predetermined conductive circuit pattern are laminated; and
one or more through-holes provided so as to entirely pass through the insulation substrate part, the upper conductive circuit pattern part and the lower conductive circuit pattern part, and configured to electrically connect the upper conductive circuit pattern part and the lower conductive circuit pattern part,
wherein the upper conductive circuit pattern part and the lower conductive circuit pattern part have an unbalanced structure in a vertical direction based on the insulation substrate part.

25. The printed circuit board of claim 24, wherein the upper conductive circuit pattern part and the lower conductive circuit pattern part may independently have a mono-layer structure or a multi-layer structure having two or more layers.

26. The printed circuit board of claim 24, wherein the upper and the lower conductive circuit patterns included in each unit layers have an unbalanced structure in view of a thickness, a shape, a structure or all of them based on the insulation substrate part.

27. The printed circuit board of claim 24, wherein the insulation substrate part and an insulation layer included in each unit layer independently have a different constitution in view of contents of a constituent resin, a material of a constituent resin, a coefficient of thermal expansion of the insulation layer, or a thickness of the insulation layer.

28. A laminated body for forming a printed circuit board, comprising:
a separation member in which first conductive layers and second conductive layers separable from each other are sequentially provided on each of upper and lower surfaces of a separating-insulation member;
laminating-insulation members sequentially laminated on upper and lower surfaces of the separation member, respectively; and
conductive layers sequentially laminated on upper and lower surfaces of the insulation members, respectively.

29. The laminated body of claim 28, wherein the first conductive layer and the second conductive layer comprise an adhesive layer interposed therebetween, and when force equal to or larger than 0.02 kgf/cm is applied, the first conductive layer and the second conductive layer are separated.

30. A printed circuit board comprising the laminated body for forming the printed circuit board of claim 28.
